(19) United States
(12) Patent Application Publication
(10) Pub. No.: US 2024/0224738 A1
(43) Pub. Date: Jul. 4, 2024

(54) DISPLAY PANEL

(71) Applicant: Shenzhen China Star Optoelectronics Semiconductor Display Technology Co., Ltd., Shenzhen (CN)

(72) Inventors: Yuwen CHEN, Shenzhen (CN); Chenglei NIE, Shenzhen (CN)

(73) Assignee: Shenzhen China Star Optoelectronics Semiconductor Display Technology Co., Ltd., Shenzhen (CN)

(21) Appl. No.: 18/508,484

(22) Filed: Nov. 14, 2023

(30) Foreign Application Priority Data
Dec. 30, 2022 (CN) 202211736378.9

(51) Int. Cl. H10K 59/80; H10K 59/35

(52) U.S. Cl. CPC H10K 59/877; H10K 59/35

(57) ABSTRACT

A display panel includes a light-emitting layer, an encapsulation layer, a first light scattering layer, and a second light scattering layer. The light-emitting layer includes a plurality of light-emitting elements. The encapsulation layer is located on a light emitting side of the light-emitting layer. The first light scattering layer, disposed between the light-emitting layer and the encapsulation layer, overlaps with the plurality of the light-emitting elements. The second light scattering layer is disposed on a side of the encapsulation layer away from the light-emitting layer, and located between the plurality of light-emitting elements.

### CROSS REFERENCE TO RELATED APPLICATION

This application claims the priority of Chinese Patent Application No. 202211736378.9, entitled “DISPLAY PANEL”, filed on Dec. 30, 2022, the disclosure of which is incorporated herein by reference in its entirety.

### FIELD OF THE DISCLOSURE

The present disclosure relates to the field of display technology, in particular to a display panel.

### BACKGROUND

Electroluminescent devices are distinguished from photoluminescent devices in that they refer to the process in which energy is released in the form of light during the transition to the ground state after electrons and holes are compounded into excitons by applying an electric current to the device. At present, the electroluminescent devices have the problem of low luminous efficiency.

Therefore, a technical scheme needs to be proposed to improve the luminous efficiency of electroluminescent devices.

### SUMMARY

An object of the present disclosure is to provide a display panel to improve the light output efficiency of the display panel.

To achieve the above objectives, a display panel includes a light-emitting layer, an encapsulation layer, a first light scattering layer, and a second light scattering layer. The light-emitting layer includes a plurality of light-emitting elements. The encapsulation layer is located on a light emitting side of the light-emitting layer. The first light scattering layer, disposed between the light-emitting layer and the encapsulation layer, overlaps with the plurality of the light-emitting elements. The second light scattering layer is disposed on a side of the encapsulation layer away from the light-emitting layer, and is located between the plurality of light-emitting elements.

In some embodiments, the first light scattering layer and the second light scattering layer both comprise a light-transmitting substrate and scattering particles dispersed in the light-transmitting substrate.

In some embodiments, a material of the scattering particles comprises at least one of molybdenum oxide, zirconia, alumina, antimony oxide, titanium oxide, niobium oxide, yttrium oxide, vanadium oxide, and scandium oxide.

In some embodiments, a size of the scattered particle ranges between 200 nm and 400 nm.

In some embodiments, the display panel according further includes a quantum dot color conversion layer, located on a side of the second light scattering layer away from the encapsulation layer.

In some embodiments, each of the light-emitting elements comprises a blue organic light-emitting layer. The quantum dot color conversion layer includes a first color conversion unit and a second color conversion unit. The first color conversion unit overlaps one of the light-emitting elements, and is used for converting light emitted by the light-emitting element into red light. The second color conversion unit overlaps one of the light-emitting elements, and is used for converting light emitted by the light-emitting element into green light.

In some embodiments, the quantum dot color conversion layer further comprises a light transmission scattering unit overlapping the one of the light-emitting elements. The light transmission scattering unit, the first color conversion unit, and the second color conversion unit constitute a repeating unit.

In some embodiments, each of the light-emitting elements further comprises a green organic light-emitting layer. For each light-emitting element, a number of green organic light-emitting layers is less than a number of the blue-light organic light-emitting layer.

In some embodiments, the display panel further includes a filter layer, located on a side of the quantum dot color conversion layer far from the second light scattering layer.

In some embodiments, the encapsulation layer comprises a glass-encapsulated substrate.

To achieve the above objectives, a display panel includes a light-emitting layer, an encapsulation layer, a quant um dot color conversion layer, and a second light scattering layer. The light-emitting layer includes a plurality of light-emitting elements. The encapsulation layer is located on a light emitting side of the light-emitting layer. The second light scattering layer is disposed on a side of the encapsulation layer away from the light-emitting layer, and located between the plurality of light-emitting elements. The quantum dot color conversion layer is located on a side of the second light scattering layer away from the encapsulation layer.

In some embodiments, the display panel further includes a first light scattering layer, disposed between the light-emitting layer and the encapsulation layer, and overlapping with the plurality of the light-emitting elements.

In some embodiments, the first light scattering layer and the second light scattering layer both comprise a light-transmitting substrate and scattering particles dispersed in the light-transmitting substrate.

In some embodiments, a material of the scattering particles comprises at least one of molybdenum oxide, zirconia, alumina, antimony oxide, titanium oxide, niobium oxide, yttrium oxide, vanadium oxide, and scandium oxide.

In some embodiments, a size of the scattered particle ranges between 200 nm and 400 nm.

In some embodiments, each of the light-emitting elements comprises a blue organic light-emitting layer. The quantum dot color conversion layer includes a first color conversion unit and a second color conversion unit. The first color conversion unit overlaps one of the light-emitting elements, and is used for converting light emitted by the light-emitting element into red light. The second color conversion unit overlaps one of the light-emitting elements, and is used for converting light emitted by the light-emitting element into green light.

In some embodiments, the quantum dot color conversion layer further comprises a light transmission scattering unit overlapping the one of the light-emitting elements, and the light transmission scattering unit, the first color conversion unit, and the second color conversion unit constitute a repeating unit.

In some embodiments, each of the light-emitting elements further comprises a green organic light-emitting layer. For each light-emitting element, a number of green organic light-emitting layers is less than a number of the blue-light organic light-emitting layer.

In some embodiments, the display panel further comprises a filter layer, located on a side of the quantum dot color conversion layer far from the second light scattering layer.

In some embodiments, the encapsulation layer comprises a glass-encapsulated substrate.

Since the first light scattering layer is disposed between the light-emitting layer and the encapsulation layer and overlaps with the plurality of light-emitting elements, the second light scattering layer is provided on the side of the encapsulation layer away from the light-emitting layer and is located between multiple light-emitting elements, the first light scattering layer scatters the light emitted by the light-emitting layer to improve the light output efficiency of the light-emitting layer, and the second light scattering layer further scatters the light from the encapsulation layer to the light-emitting element, to improve the light output efficiency of the display panel.

### BRIEF DESCRIPTION OF THE DRAWINGS

FIG. 1 is a cross-sectional view of a display panel according to an embodiment of the present disclosure.

### DETAILED DESCRIPTION OF PREFERRED EMBODIMENTS

The following will be combined with the accompanying drawings in the embodiment of the present disclosure, the technical solution in the embodiment of the present disclosure is clearly and completely described. Obviously, the described embodiments are only a subset of embodiments of the present disclosure, not all embodiments. Based on the embodiments in the present disclosure, all other embodiments obtained by those skilled in the art without performing creative labor are within the scope of protection of the present disclosure.

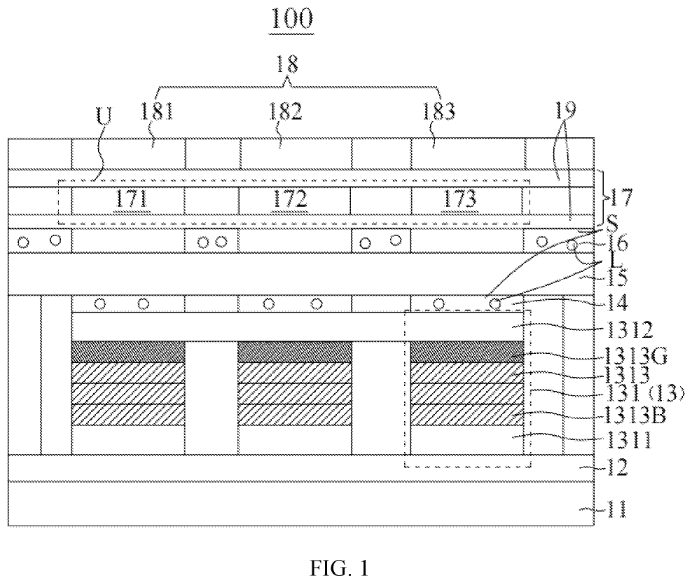

Referring to FIG. 1, FIG. 1 is a cross-sectional view of a display panel according to an embodiment of the present disclosure. A display panel 100 includes a substrate 11, a driving circuit layer 12, a light-emitting layer 13, a first light scattering layer 14, an encapsulation layer 15, a second light scattering layer 16, a quantum dot color conversion layer 17 and a filter layer 18.

In the present embodiment, the substrate 11 is a glass substrate, but not limited thereto, the substrate 11 may also be a flexible substrate.

In the present embodiment, the driving circuit layer 12 is disposed on the substrate 11. The driving circuit layer 12 includes a plurality of driving circuits (not shown). The driving circuit may be a two-transistor-and-one-capacitor (2TIC) circuit, 3TIC circuit, 4TIC circuit, 5TIC circuit, 6TIC circuit, and 7TIC circuit, where T represents a thin-film transistor and C represents a capacitor.

In the present embodiment, the light-emitting layer 13 is disposed on the surface of the driving circuit layer 12 away from the substrate 11. The light-emitting layer 13 includes a plurality of light-emitting elements 131. Each light-emitting element 131 is electrically connected to one of the driving circuits. Each light-emitting element 131 includes a first electrode 1311, a second electrode 1312, and at least one organic light-emitting layer 1313 disposed between the first electrode 1311 and the second electrode 1312. Two or more light-emitting elements 131 share a second electrode 1312.

One of the organic light-emitting layers 1313 comprises at least one blue light-emitting layer 1313B to make the plurality of light-emitting layers 13 emit blue light. Multiple blue light organic light-emitting layers 1313B are provided in each light-emitting element 131 to improve the brightness and service life of each light-emitting element 131.

In the present embodiment, each light-emitting element 131 further comprises on re or more green organic light-emitting layers 1313G. A number of green organic light-emitting layers 1313G in each light-emitting element 131 is less than the number of blue organic light-emitting layers 1313B in each light-emitting element 131, so that the light-emitting element 131 can emit blue light and green light to further improve the brightness and service life of the light-emitting element 131.

For example, each light-emitting element 131 includes three adjacent blue light organic light-emitting layer 1313B and one green organic light-emitting layer 1313G. The green organic light-emitting layer 1313G and three adjacent blue light organic light-emitting layer 1313B are stacked. The green organic light-emitting layer 1313G is disposed close to the second electrode 1312.

It is noted that the luminous frequency of green light is higher than that of red light. The light-emitting element 131 emitting green light which can serve as a light stimulus source to produce red light can improve the brightness and life of the light-emitting element 131.

It can be understood that in other embodiments, the organic light-emitting layer 1313 of different light-emitting elements 131 may also include an organic light-emitting layer emitting different colors, for example, the organic light-emitting layer 1313 of the three light-emitting elements 131 may include a red organic light-emitting layer, a blue organic light-emitting layer and a green organic light-emitting layer.

In the present embodiment, the encapsulation layer 15 is located on the light outlet side of the light-emitting layer 13. The encapsulation layer 15 includes a glass-encapsulated substrate. The encapsulation layer 15 and the substrate 11 are connected by a sealing adhesive.

The encapsulation layer 15 may also include two inorganic layers and an organic layer therebetween. The two inorganic layers include at least one of silicon nitride, silicon oxide, and silicon nitride. The organic layer includes at least one of polyamide, polysilane, and polyacrylates.

In the present embodiment, the first light scattering layer 14 serves as the internal light extraction structure to decrease light lost of the light emitted by the light-emitting element 131 between the organic light-emitting layer and the encapsulation layer 15 due to multiple total reflection, that is, to improve the light lost due to wave modes.

The first light scattering layer 14 is disposed between the light-emitting layer 13 and the encapsulation layer 15. The first light scattering layer 14 overlaps with a plurality of light-emitting elements 131, so that the first light scattering layer 14 scatters the light emitted by a plurality of light-emitting elements 131, and improves the efficiency of the light incident emitted by the plurality of light-emitting elements 131 into the encapsulation layer 15.

Specifically, a plurality of first light scattering layer 14 and a plurality of light-emitting elements 131 overlap one-to-one, and each first light scattering layer 14 covers a corresponding light-emitting element 131.

In the present embodiment, the second light scattering layer 16 serves as the internal light extraction structure to decrease light lost of the light emitted by the light-emitting element 131 after incident to the encapsulation layer 15 at the interface between the encapsulation layer 15 and the air due to multiple total reflection, that is, to improve the light lost due to substrate modes.

The second light scattering layer 16 is disposed on the side of the encapsulation layer 15 away from the light-emitting layer 13 and is located between a plurality of light-emitting elements 131. When the plurality of light-emitting elements 131 emit light, the emitted light can be further scattered by the second light scattering layer 16, raising light output efficiency of the light emitted by the light-emitting element 131 incident into the air from the encapsulation layer 13.

Specifically, the second light scattering layer 16 is located on the surface of the encapsulation layer 15 away from the light-emitting layer 13, and the orthographic projection of the second light scattering layer 16 on the substrate 11 is located between the orthographic projection of a plurality of light-emitting elements 131 on the substrate 11.

In the present embodiment, the first light scattering layer 14 and the second light scattering layer 16 both include a light-transmitting substrate S and scattering particles L dispersed in the light-transmitting substrate S.

The scattered particle L has a particle size ranging between 200 nanometers and 400 nanometers. Materials of the scatter particle L include at least one of molybdenum oxide, zirconia, alumina, antimony oxide, titanium oxide, niobium oxide, yttrium oxide, vanadium oxide, and scandium oxide. The light-transmitting substrate S includes a polyimide film, a polyester film, a polyethylene film, a polypropylene film, a polyvinyl chloride film, a polystyrene film and an acrylonitrile-butadiene-styrene copolymer film.

In the present embodiment, the thickness of the first light scattering layer 14 and the second light scattering layer 16 ranges between 200 nm and 800 nm, for example, the thickness of the first light scattering layer 14 and the second light scattering layer 16 is 250 nm, 300 nm, 350 nm, 400 nm, 450 nm, 500 nm, 550 nm, 600 nm, 650 nm, 700 nm, 750 nm or 800 nm.

In the present embodiment, the quantum dot color conversion layer 17 is located on the side of the second light scattering layer 16 away from the encapsulation layer 15.

Since the design of the first light scattering layer 14 and the second light scattering layer 16, the extraction efficiency of the light stimulus source incident to the quantum dot color conversion layer 17 is improved. Because the light emitted by the light-emitting layer 13 is used as a light stimulus source, the scattering effect of the first light scattering layer 14 with the second light scattering layer 16 will not cause color mixing problems. In addition, the extraction efficiency of the photostimulus incident to the quantum dot color conversion layer 17 is improved, so that the intensity of the photostimulus source is increased, and the display panel 100 only needs a lower driving current when the display panel 100 displays the same brightness, which can enhance the luminous display efficiency of the display panel 100, and at the same time help reduce the power consumption of the display panel.

The quantum dot color conversion layer 17 further comprises a first color conversion unit 171, a second color conversion unit 172 and a light transmission scattering unit 173. The light transmission scattering unit 173 overlaps one of the light-emitting elements 131. The first color conversion unit 171 overlaps one of the light-emitting elements 131, the second color conversion unit 172 overlaps one of the light-emitting elements 131. The first color conversion unit 171 is used to convert the light emitted by the light-emitting element 131 into red light, the second color conversion unit 172 is used to convert the light emitted by the light-emitting element 131 into green light, the light transmission scattering unit 173 is used to scatter the light emitted by the light-emitting element 131. The light transmission scattering unit 173, first color conversion unit 171 and second color conversion unit 172 constitute a repeating unit U. There are multiple repeating units U in the display panel 100.

The first color conversion unit 171 and the second color conversion unit 172 both include quantum dots, including but not limited to CdSe, CdS, ZnS, ZnSe, CdTe, InP, and GaN. Quantum dots have a particle size ranging between 1 nanometer and 10 nanometers.

The light transmission scattering unit 173 includes transparent medium and scattering particles dispersed in a transparent medium. The scattering particle material comprises at least one of molybdenum oxide, zirconia, alumina, antimony oxide, titanium oxide, niobium oxide, yttrium oxide, vanadium oxide and scandium oxide. A material of the transparent media includes at least one of polyimide, polyester, polyethylene, polypropylene, polyvinyl chloride, polystyrene, and acrylonitrile-butadiene-styrene copolymer films.

In the present embodiment, the opposite sides of the quantum dot color conversion layer 17 are also provided with an encapsulation film 19 to protect the quantum dot color conversion layer 17. The material of the encapsulation film 19 includes, but is not limited to, organic materials.

In the present embodiment, the filter layer 18 is located on the side of the quantum dot color conversion layer 17 away from the second light scattering layer 16, in order to reduce the reflection of ambient light of the display panel 100, and improve the contrast of the display panel 100 when displayed. The filter layer 18 includes a first color resistance 181, a second color resistance 182 and a third color resistance 183. The first color resistance 181 is a red color resistance and corresponds to the first color conversion unit 171, the second color resistance 182 is a green color resistance and corresponds to the second color conversion unit 172, the third color resistance 183 is a blue color resistance and corresponds to the light transmission scattering unit 173.

Since the first light scattering layer is disposed between the light-emitting layer and the encapsulation layer and overlaps with the plurality of light-emitting elements, the second light scattering layer is provided on the side of the encapsulation layer away from the light-emitting layer and is located between multiple light-emitting elements, the first light scattering layer scatters the light emitted by the light-emitting layer to improve the light output efficiency of the light-emitting layer, and the second light scattering layer further scatters the light from the encapsulation layer to the light-emitting element, to improve the light output efficiency of the display panel.

The description of the above embodiments is only used to help understand the technical solution of the present disclosure and its core idea. Ordinary skill in the art should understand that it may still modify the technical solution described in the foregoing embodiments, or replace some of the technical features equivalently; and these modifications or replacements do not make the essence of the corresponding technical solution out of the scope of the technical solution of each embodiment of the present disclosure.

What is claimed is:

1. A display panel comprising:
a light-emitting layer, comprising a plurality of light-emitting elements;
an encapsulation layer, located on a light emitting side of the light-emitting layer;
a first light scattering layer, disposed between the light-emitting layer and the encapsulation layer, and overlapping with the plurality of the light-emitting elements; and
a second light scattering layer, disposed on a side of the encapsulation layer away from the light-emitting layer, and located between the plurality of light-emitting elements.

2. The display panel according to claim 1, wherein the first light scattering layer and the second light scattering layer both comprise a light-transmitting substrate and scattering particles dispersed in the light-transmitting substrate.

3. The display panel according to claim 2, wherein a material of the scattering particles comprises at least one of molybdenum oxide, zirconia, alumina, antimony oxide, titanium oxide, niobium oxide, yttrium oxide, vanadium oxide, and scandium oxide.

4. The display panel according to claim 2, wherein a size of the scattered particle ranges between 200 nm and 400 nm.

5. The display panel according to claim 1, further comprising:
a quantum dot color conversion layer, located on a side of the second light scattering layer away from the encapsulation layer.

6. The display panel according to claim 5, wherein each of the light-emitting elements comprises a blue organic light-emitting layer, and the quantum dot color conversion layer comprises:
a first color conversion unit, overlapping one of the light-emitting elements, for converting light emitted by the light-emitting element into red light; and
a second color conversion unit, overlapping one of the light-emitting elements, for converting light emitted by the light-emitting element into green light.

7. The display panel according to claim 6, wherein the quantum dot color conversion layer further comprises a light transmission scattering unit overlapping the one of the light-emitting elements, and the light transmission scattering unit, the first color conversion unit, and the second color conversion unit constitute a repeating unit.

8. The display panel according to claim 6, wherein each of the light-emitting elements further comprises a green organic light-emitting layer, and wherein for each light-emitting element, a number of green organic light-emitting layers is less than a number of the blue-light organic light-emitting layer.

9. The display panel according to claim 5, further comprising a filter layer, located on a side of the quantum dot color conversion layer far from the second light scattering layer.

10. The display panel according to claim 1, wherein the encapsulation layer comprises a glass-encapsulated substrate.

11. A display panel comprising:
a light-emitting layer, comprising a plurality of light-emitting elements;
an encapsulation layer, located on a light emitting side of the light-emitting layer;
a second light scattering layer, disposed on a side of the encapsulation layer away from the light-emitting layer, and located between the plurality of light-emitting elements; and
a quantum dot color conversion layer, located on a side of the second light scattering layer away from the encapsulation layer.

12. The display panel according to claim 11, further comprising a first light scattering layer, disposed between the light-emitting layer and the encapsulation layer, and overlapping with the plurality of the light-emitting elements.

13. The display panel according to claim 12, wherein the first light scattering layer and the second light scattering layer both comprise a light-transmitting substrate and scattering particles dispersed in the light-transmitting substrate.

14. The display panel according to claim 13, wherein a material of the scattering particles comprises at least one of molybdenum oxide, zirconia, alumina, antimony oxide, titanium oxide, niobium oxide, yttrium oxide, vanadium oxide, and scandium oxide.

15. The display panel according to claim 13, wherein a size of the scattered particle ranges between 200 nm and 400 nm.

16. The display panel according to claim 11, wherein each of the light-emitting elements comprises a blue organic light-emitting layer, and the quantum dot color conversion layer comprises:
a first color conversion unit, overlapping one of the light-emitting elements, for converting light emitted by the light-emitting element into red light; and
a second color conversion unit, overlapping one of the light-emitting elements, for converting light emitted by the light-emitting element into green light.

17. The display panel according to claim 11, wherein the quantum dot color conversion layer further comprises a light transmission scattering unit overlapping the one of the light-emitting elements, and the light transmission scattering unit, the first color conversion unit, and the second color conversion unit constitute a repeating unit.

18. The display panel according to claim 17, wherein each of the light-emitting elements further comprises a green organic light-emitting layer, and wherein for each light-emitting element, a number of green organic light-emitting layers is less than a number of the blue-light organic light-emitting layer.

19. The display panel according to claim 11, further comprising a filter layer, located on a side of the quantum dot color conversion layer far from the second light scattering layer.

20. The display panel according to claim 11, wherein the encapsulation layer comprises a glass-encapsulated substrate.
